(19) United States
(12) Patent Application Publication
(10) Pub. No.: US 2024/0417872 A1
(43) Pub. Date: Dec. 19, 2024

(54) METHOD OF FABRICATING A CATALYST ON A SUBSTRATE

(71) Applicant: AUSTRALIAN NATIONAL UNIVERSITY, Australian Capital Territory (AU)

(72) Inventors: Siva Krishna KARUTURI, Australian Capital Territory (AU); Chennupati JAGADISH, Forestville, New South Wales (AU); Hark Hoe TAN, Australian Capital Territory (AU); Bikesh GUPTA, Australian Capital Territory (AU); Joshua Zheyan SOO, Australian Capital Territory (AU)

(73) Assignee: AUSTRALIAN NATIONAL UNIVERSITY, Australian Capital Territory (AU)

(21) Appl. No.: 18/703,206

(22) PCT Filed: Oct. 21, 2022
(86) PCT No.: PCT/AU2022/051271

§ 371 Date: Apr. 19, 2024

(30) Foreign Application Priority Data
Oct. 22, 2021 (AU) 2021903393

(51) Int. Cl. C25B 11/053; C23C 14/16; C23C 14/30; C23C 14/34; C23C 28/00; C25B 11/061; C25B 11/087; C25D 3/12; C25D 5/48; C25D 7/12

(52) U.S. Cl. CPC C25B 11/053; C23C 14/16; C23C 14/30; C23C 14/34; C23C 28/321; C23C 28/34; C25B 11/061; C25B 11/087; C25D 3/12; C25D 5/48; C25D 7/126

(57) ABSTRACT

A method of fabricating a catalyst on a substrate comprising: providing a substrate having a layer of metal thereon; and contacting the layer of metal with a corrosive solution to form the catalyst.

### TECHNICAL FIELD

This disclosure relates to a method of fabricating a catalyst on a substrate. This disclosure also relates to method of regenerating a catalyst on a metal surface. This disclosure also relates to a catalyst fabricated with the method disclosed herein. This disclosure also relates to a substrate and an electrode comprising a catalyst fabricated with the method disclosed herein.

### BACKGROUND

With climate change being an increasingly pertinent issue, there is a greater urgency in transitioning away from fossil fuels to renewable energy sources in energy production. Converting the presently intermittent renewable resources to stable and storable chemical fuels is a key measure in ensuring sustainable delivery of renewable energy to consumers.

Hydrogen generation via water splitting, whereby water molecules are separated into hydrogen and oxygen at the cathode and anode electrodes, respectively, is an attractive alternative to conventional renewable energy generation methods. Hydrogen, when used as a fuel in fuel cells, presents numerous advantages, such as high gravimetric energy density, thereby allowing for an efficient energy generation. Additionally, hydrogen generation is harmless for the environment emitting only water as a by-product.

From an industrial perspective, alkaline water splitting (AWS) systems hold particularly great promise due to their relative ease of scalability and greater versatility due the larger range of catalysts, including cheaper non noble-metal catalysts, used in the hydrogen production process.

Therefore, the solar-driven production of molecular hydrogen from water is a vital component of a future clean hydrogen economy.

The challenge in the development of electrodes suitable for AWS remains manifold. Ensuring high performance in anode electrocatalysts is critical, considering the necessity to overcome the relatively sluggish kinetics of oxygen evolution reaction (OER) as compared to hydrogen evolution reaction (HER) at the cathode.

Catalysis, or electrocatalysis, has played a major role in overcoming the kinetic energy barriers for electrochemical reactions of water, oxygen, and hydrogen in water-splitting cells and fuel cells.

However, the range of catalyst support materials is currently limited due to reaction conditions of the water splitting process and the fabrication conditions of the current catalyst fabrication methods.

The catalyst support materials are required to be electrically conductive and chemically robust against harsh corrosive conditions during water splitting operations. Additionally, the same support materials are required to exhibit good temperature stability, due to the high temperature reaction conditions of existing electrocatalyst deposition methods. Ti and steel substrates are currently the primary support material for current AWS systems, meeting all the above-mentioned criteria.

The limitations on the type of catalyst support material utilizable for hydrogen production severely affect the scalability of the process at an industrial level. There is, therefore, a need to broaden the range of materials that can be used as a catalyst support. There is also a need for cheaper alternatives such as using non-metal substrates.

There is also a need to develop highly active, stable, and inexpensive electrochemical catalysts, capable of maximizing the hydrogen production. In this regard, there is a need for catalyst systems that utilise relatively inexpensive, earth abundant materials. As used herein, “earth abundant” means present in the Earth's crust at concentrations of greater than 1 ppm.

It is to be understood that, if any prior art is referred to herein, such reference does not constitute an admission that the prior art forms a part of the common general knowledge in the art, in Australia or any other country.

### SUMMARY

According to one aspect, there is provided a method of fabricating a catalyst on a substrate comprising:
providing a substrate having a layer of metal thereon; and
contacting the layer of metal with a corrosive solution to form the catalyst.

As used herein, the term “catalyst” has its ordinary technical meaning of a material that increases the rate of a chemical reaction without itself undergoing any permanent chemical change.

The method may further comprise a step of forming the layer of metal on the substrate to form a metalized substrate.

In some embodiments, the layer of metal comprises an earth-abundant metal. The layer of metal may include one or more transition metals. The layer of metal may comprise one or more metals selected, for example, from nickel, molybdenum, iron, cobalt, copper, manganese, zinc and/or a combination thereof. Nickel (Ni) and Ni-based materials exhibit good catalytic activity in electrolytic processes, such as hydrogen generation via water splitting. Ni is also inexpensive and readily available and has shown a relatively good catalytic performance in both oxygen evolution reactions (OER) and hydrogen evolution (HER) reactions.

The thickness of the layer of metal can be tailored as desired. However, the thickness should preferably be sufficient to possess adequate structural flexibility to adhere to most support materials. Further preferably, the metal layer thickness is sufficiently thick to prevent complete film etch/removal during the solution corrosion process. Accordingly, the metal layer should comprise the required quantity of metal necessary for the corrosion process to be performed, and thereby the catalyst to be formed, while maintaining the desired conductive properties of the metal layer, required for its intended application, for example to perform as an electrode in electrochemical applications, such as hydrogen generation via water splitting.

The substrate may be completely covered by the layer of metal, such that none of the substrate is exposed during the subsequent corrosion step.

In some embodiments, the layer of metal has a minimum thickness of 0.5 μm. In some embodiments, the layer of metal has a minimum thickness of 1.0 μm. In some embodiments, the layer of metal has a minimum thickness of 1.5 μm. In some embodiments, the layer of metal has a minimum thickness of 2 micron. In some embodiments, the layer of metal has a minimum thickness of 2.5 μm.

In one embodiment, the thickness of the layer of metal is a maximum of 10 microns. In one embodiment, the thickness of the layer of metal is a maximum of 8 microns. In one embodiment, the thickness of the layer of metal is a maximum of 7 microns. In one embodiment, the thickness of the layer of metal is a maximum of 5 microns. In one embodiment, the thickness of the layer of metal is a maximum of 3 microns.

Aside from acting as sacrificial metal layer for the catalyst generation, the layer of metal serves also as a chemical protection layer for the underlying substrate which can be otherwise damaged in harsh chemical environments, such as may exist during, for example, electrolysis operations and water splitting reactions. This further eliminates the need for a chemically robust material to serve, for example, as an electrode substrate.

In some embodiments, forming the layer of metal on the substrate comprises electroplating the metal on the substrate. The layer of metal, can be, for example applied by electroplating the substrate using a metal halide electrolyte. In one embodiment the layer of metal is applied by electroplating the substrate using an electrolyte comprising a chloride solution of an earth abundant metal. The earth abundant metal may be a transition metal. In one embodiment the layer of metal is applied by electroplating the substrate with a Ni(II) chloride solution as the electrolyte, to thereby form a layer of Ni on the substrate. In another embodiment, a Ni(II) sulphate solution is used as the electrolyte to apply a layer of Ni on the substrate. In yet another embodiment, a Ni(II) acetate solution is used as the electrolyte to apply a layer of Ni on the substrate.

In some embodiments, an alternative suitable metal deposition technique may be used to apply the layer of metal on the substrate. For example, in some embodiments the layer of metal is applied by one or more of electroless plating, chemical vapour deposition or wet chemistry.

While the deposited layer of metal may comprise only a single metal, for example Ni, in other embodiments the deposited layer of metal may comprise two or more metals. The combination of metals may include nickel. The combination of metals may further include one or more of Mo, Co, Fe, Cu, Mn and Zn. Examples of metal combinations that may be in the metal layer include: Ni—Mo, Ni—Co, Ni—Fe, Ni—Fe—Cu, Ni—Mo—Zn, Ni—Fe—Mo and Ni—Mn—Fe—Mo.

In some other embodiments forming the layer of metal on the substrate comprises applying a metal plate or foil on the substrate. In some embodiments, the metal plate or foil is attached to the substrate using an adhesive layer such as Ag paint. In other embodiments the metal plate or foil is attached to the back side of the substrate by soldering.

The substrate can be selected from a broad range of materials including, but not limited to, semiconductors (such as Si and/or GaAs), metals (such as Cu mesh, Cu plate or stainless steel), non-metals and polymers (such as polyethylene terephthalate (PET), polypropylene (PP), high-density polyethylene (HDPE).

In some embodiments, the substrate is an electrode.

In one embodiment, the substrate is photovoltaic cell. In one embodiment, the substrate is a GaAs PV cell.

Where the present method is applied to the fabrication of a catalyst on a semiconductor, the method advantageously enables the avoidance of solution-induced semiconductor corrosion which can compromise the performance and lifetime of the photoelectrodes. Additionally, where the semiconductor forms part of a semiconductor-based photoelectrode device, the layer of metal formed on the semiconductor substrate during the present method protects the semiconductor during the water splitting operation, thereby stabilizing the performance of the photoelectrode device.

The present method includes contacting the layer of metal on the substrate with a corrosive solution to form the catalyst. As used herein, the term “corrosive solution” means an aqueous solution that chemically reacts with and oxidises the metal layer.

In some embodiments, contacting the layer of metal with a corrosive solution comprises dipping the substrate with the layer of metal provided thereon into the corrosive solution.

In other embodiments, contacting the layer of metal with a corrosive solution comprises spraying or otherwise applying the corrosive solution to the layer of metal.

In some embodiments, the corrosive solution is a halide solution. The corrosive solution may be, for example, a metal halide solution. In an embodiment, the corrosive solution is a transition metal halide solution.

The metal halide may be present in solution at a minimum concentration of 1 mM. In another embodiment, the metal halide may be present in solution at a minimum concentration of 1.5 mM. In another embodiment, the metal halide may be present in solution at a minimum concentration of 5 mM. In another embodiment, the metal halide may be present in solution at a minimum concentration of 10 mM.

The metal halide may be present in solution at a maximum concentration of 1 M. In an embodiment, the metal halide may be present in solution at a maximum concentration of 0.5 M. In another embodiment, the metal halide may be present in solution at a maximum concentration of 0.1 M. In another embodiment, the metal halide may be present in solution at a maximum concentration of 0.05 M. In another embodiment, the metal halide may be present in solution at a maximum concentration of 0.01 M.

The pH of the corrosive solution may be acidic. The pH may be less than 7. The pH may be at least 2. In an embodiment, the pH is at least 2.5. In another embodiment, the pH is at least 3.

The corrosive solution may include one or more metal salts. The metal salts may comprise one or more transition metal salts.

The corrosive solution may be, for example, a metal chloride solution.

The corrosive solution may comprise one or more transition metal chlorides. The transition metal chloride may comprise nickel chloride and/or iron chloride.

The corrosive solution may comprise one or more transition metal nitrates. The transition metal nitrates may comprise nickel nitrate and/or iron nitrate.

In some embodiments, the corrosive solution is a mixture of Ni(II) and Fe(III) chlorides. In other embodiments, the corrosive solution is a mixture of Ni(II) and Fe(III) nitrates.

The molar ratio of Ni:Fe may be at least 1:2. In an embodiment, the molar ratio is a maximum of 2:1. In one embodiment, the molar ratio of the mixture of Ni(II) and Fe(III) chloride or the mixture of Ni(II) and Fe(III) nitrates is 1:1. In another embodiment, the molar ratio of the mixture of Ni(II) and Fe(III) chloride or the mixture of Ni(II) and Fe(III) nitrates is 1:2. In yet another embodiment, the molar ratio of the mixture of Ni(II) and Fe(III) chloride or the mixture of Ni(II) and Fe(III) nitrates is 2:1.

The temperature of the corrosion step may be ambient or elevated. By “elevated temperature” is meant a temperature that is higher than ambient. In some embodiments, the step of contacting the layer of metal to a corrosive solution is performed at room temperature. In other embodiments, the step of contacting the layer of metal to a corrosive solution is performed at a minimum of 40° C. In other embodiments, the step of contacting the layer of metal to a corrosive solution is performed at a minimum of 60° C. In yet other embodiments, the step of contacting the layer of metal to a corrosive solution is performed at a maximum of the 90° C. In yet other embodiments, the step of contacting the layer of metal to a corrosive solution is performed at a maximum of 80° C.

The metal layer may be exposed to the corrosion solution for a sufficient amount of time to initiate the corrosion of the metal and form a corrosion product. The exposure time of the layer of metal to the corrosive solution can be adjusted as desired, with a longer time providing a larger conversion of metal to catalyst. The optimum amount of time will be dependent on a number of factors including concentration and temperature of the corrosion solution. The metal layer may be exposed to the corrosion solution for a period of time up to 60 minutes. In an embodiment, the metal layer is exposed to the corrosion solution for a period of time up to 30 minutes. In another embodiment, the metal layer is exposed to the corrosion solution for a period of time up to 15 minutes. In another embodiment, the metal layer is exposed to the corrosion solution for a period of time up to 10 minutes. In another embodiment, the metal layer is exposed to the corrosion solution for a period of time up to 5 minutes.

During the corrosion step, the corrosive solution reacts with at least some of the metal in the metal layer to form a corrosion product. The corrosion product may form in situ at the outer surface of the metal layer, such that a layer of corrosion product forms on the unreacted metal of the metal layer. The corrosion product may comprise the catalyst.

In some embodiments, the catalyst is an electrocatalyst.

In some embodiments, the catalyst comprises one or more metal hydroxides.

In some embodiments, the catalyst comprises a monometallic hydroxide.

In some embodiments, the catalyst is a multimetallic hydroxide.

In some embodiments, the catalyst is a multimetallic layered double hydroxide (LDH).

In some embodiments, the catalyst includes one or more transition metals. The one or more transition metals may be selected from Ni, Fe, Co, Mo and Cu. The catalyst may include at least nickel. In some embodiments, the catalyst is selected from NiFe hydroxide, NiCoFe hydroxide, NiMo hydroxide, NiCuFe hydroxide and/or a combination thereof.

In an embodiment, when the layer of metal is contacted with the corrosive solution, a redox process occurs at the metal surface, wherein the metal is oxidised and thereby forming monometallic or multimetallic layered double hydroxides (LDH) catalysts.

In one embodiment, the catalyst is a NiFe LDH catalyst.

In some embodiments, the method further includes applying a seed layer to the substrate prior to forming or applying the layer of metal. The seed layer may facilitate the adhesion of the layer of metal to the substrate.

In some embodiments, the seed layer has a minimum thickness of 50 nm

In some embodiments, the thickness of the seed layer is approximately 100 nm.

In some embodiments, the composition of the seed layer includes Ti and/or Ni.

In some embodiments, the seed layer includes at least one of a layer of Ti and a layer of Ni.

In some embodiments, the layer of Ti has a minimum thickness of 50 nm.

In some embodiments, the layer of Ni has a minimum thickness of 50 nm.

In some embodiments, applying a seed layer to the substrate comprises depositing the seed layer by electron beam evaporation. In some other embodiments, applying a seed layer to the substrate comprises depositing the seed layer by thermal evaporation. In yet some embodiments, applying a seed layer to the substrate comprises depositing the seed layer by sputter deposition.

According to another aspect, there is provided a method of regenerating a catalyst on a metal surface, the method including:
removing any spent or residual catalyst from the metal surface to produce a cleaned metal surface; and
contacting the cleaned metal surface with a corrosive solution to regenerate fresh catalyst thereon.

The method provides an effective way of regenerating a catalyst on a used metal or metal plated substrate, further reducing the cost involved in replacing a metal substrate or redepositing fresh substrates before generating fresh catalyst thereon.

In some embodiments, the metal surface comprises a surface of a metal foil.

In other embodiments, the metal surface comprises a metallised surface of a substrate.

In some embodiments, removing any spent or residual catalyst from the metal surface comprises treating the metal surface with an etchant.

In some embodiments, the etchant comprises a mineral acid. In one embodiment, the etchant includes hydrochloric acid (HCl). In some other embodiments, the etchant includes sulphuric acid (H₂SO₄). In some other embodiments, the etchant includes a combination of hydrochloric acid (HCl) and sulphuric acid (H₂SO₄).

According to another aspect, there is provided a catalyst fabricated by the method according to any of the embodiments discussed above.

According to another aspect, there is provided a substrate comprising thereon a catalyst fabricated according to any of the embodiments discussed above.

According to another aspect, there is provided an electrode comprising a catalyst fabricated by the method according to any of the embodiments discussed above.

Advantages of the present method include:
The method can be inexpensive,
It can be applied to a variety of metallic surfaces
The method does not require elevated temperatures. It can be conducted at ambient temperature.
Given that the method can largely occur on the metal surface and may not require high temperature activity, the substrate may comprise a wide variety of compositions having a suitable thin conductive metal layer thereon.

### BRIEF DESCRIPTION OF THE DRAWINGS

Embodiments will now be described by way of example only, with reference to the accompanying drawings in which:

FIG. 1 is a schematic diagram showing embodiments of the fabrication process disclosed herein.

FIG. 2 shows photographs of electroplated Ni on various substrates before and after the formation of NiFe LDH.

FIG. 3(a) is an EDS mapping image of a cross-section region of NiFe LDH formed on a Ni surface. Reference EDS mapping images of Ni, Fe and O are shown on the right.

FIG. 3(b)-(c) are SEM images of (b) Ni electroplated on a Si surface and (c) NiFe LDH formed on a Ni surface.

FIGS. 4(a)-(c) are graphs showing performance comparisons between Ni electroplated Si with and without NiFe LDH catalyst: (a) Forward LSV scans at 0.01 V/s and (b) EIS Nyquist spectra at 1.49 V vs RHE. (c) Chronopotentiometric results for NiFe LDH catalyst formed on Ni deposited on various substrates at 10 mA cm⁻².

FIGS. 4(d)-(e) Overpotential measurements of NiFe LDH: (d) at 10 and 50 mA cm⁻² deposited on various substrates and (e) at 10 mA cm⁻² after various deposition and etch times in 0.1 M HCl (Si substrate).

FIG. 5(a) is a schematic illustration of a GaAs PV-assisted photoanode with rear-deposited NiFe LDH.

FIG. 5(b)-(d) are graphs showing the current-voltage and the chronoamperometric characteristics of the photoanode of FIG. 4(a). (b) J-V curve of photoanode with respective Applied bias photon-to-current efficiency (ABPE) in 1.0 M KOH measured under AM 1.5 G 1 sun illumination, (c) Incident Photon-to-current Conversion efficiency (IPCE) of GaAs PV-assisted photoelectrode with NiFe LDH catalyst measured in relation to AM 1.5 G solar spectrum and (d) Chronoamperometric results at 1.3 V vs RHE.

### DETAILED DESCRIPTION

In the following detailed description, reference is made to the accompanying drawings which form a part of the detailed description. The illustrative embodiments described in the detailed description, depicted in the drawings and defined in the claims, are not intended to be limiting. Other embodiments may be utilised and other changes may be made without departing from the spirit or scope of the subject matter presented. It will be readily understood that the aspects of the present disclosure, as generally described herein and illustrated in the drawings can be arranged, substituted, combined, separated and designed in a wide variety of different configurations, all of which are contemplated in this disclosure.

The present disclosure provides a method of fabricating a catalyst on a variety of substrates and/or support materials. The method comprises the steps of (i) applying a layer of metal on the substrate to form a metalized substrate; and (ii) contacting the layer of metal to a corrosive solution to form a layer of the catalyst.

The method for fabricating a catalyst on a substrate will now be described by way of example and with reference to the figures.

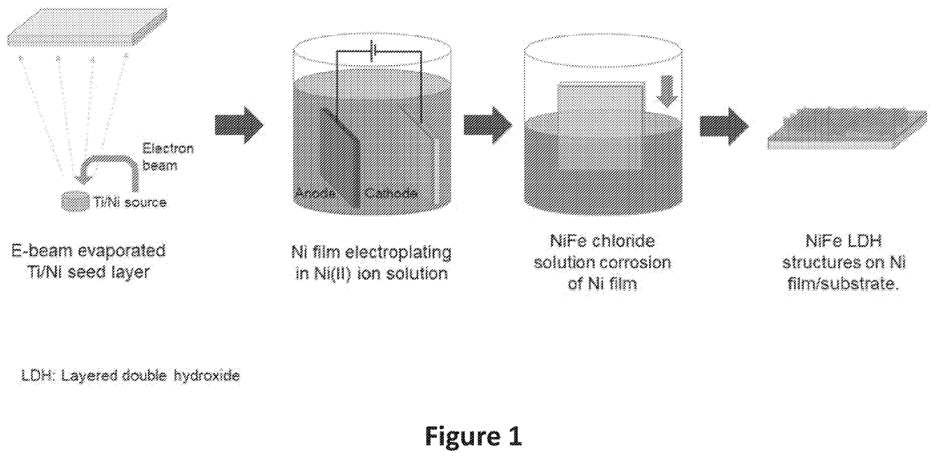

According to the embodiment schematically shown in FIG. 1, the method includes applying a seed layer to the substrate prior to applying the layer of metal, such that the seed layer facilitates the adhesion of the layer of metal to the substrate.

In the described embodiment, the seed layer is deposited on one side of the substrate using electron beam evaporation. However, any other suitable deposition technique can be used. For example, in some embodiments the seed layer is applied by chemical bath deposition.

In the described embodiment, the composition of the seed layer includes Ti and Ni. In particular, the seed layer is composed by a 50 nm layer of Ti and a 50 nm layer of Ni. In the described embodiment, the layer of Ti is deposited on the substrate and the Ni layer is deposited on top of the Ti layer.

The seed layer improves or provides conductivity to the underlying substrate. Additionally, the Ti layer helps to improve the adhesion of the metal layer (in this case Ni layer) during the subsequent plating process.

However, the composition and the thickness of the seed layer can be selected as desired and tailored to the specific use of the catalyst in catalytic processes.

The substrate shown in FIG. 1 has an approximate geometric area of 1 cm². However, the method is scalable and can be applied to much larger areas.

According to the described embodiment, after the deposition of the seed layer, a layer of metal is applied to the substrate by electroplating. It should be noted that the deposition of the seed layer is optional, and, in some embodiments, the layer of metal is applied directly on the substrate.

In the described embodiment, a layer of Ni is applied by electroplating. In particular, a Ni(II) chloride solution is used as the electrolyte to deposit the layer of Ni on the substrate.

The electrodeposition is performed at 20 mA/cm² using a 0.36 M Ni(II) chloride solution.

Although not apparent from the schematic shown in FIG. 1, the thickness of the metal layer according to the described embodiment is approximately 2-3 micron. However, the thickness of the layer of metal can be tailored as desired and/or according to specific requirements of a catalyst reaction.

Referring to FIG. 1, after the Ni electroplating of the substrate, the layer of deposited metal is contacted with a corrosive solution by dipping the substrate in the corrosive solution. The corrosive reaction converts part of deposited metal into a catalytic material as described in more detailed below with reference to the described embodiment.

In the described embodiment, the substrate is dipped for 1 minute into a 15 mM solution mixture of Ni(II) and Fe(III) chloride at 1:1 molar ratio. The chloride ions in the solution initiate the corrosion process of the electroplated Ni layer to form NiFe double hydroxides at the film surface. The substrate is then dried at 70° C. for 1 hour.

### EXAMPLE

Substrates made of different materials, including semiconductors (Si and GaAs), metals (Cu mesh, Cu plate, stainless steel) and a polymer (PET), were coated using the method described in FIG. 1. In particular, one side of the substrates (approximate geometric area: 1 cm²) was coated with a layer of Ti/Ni (50 nm/50 nm) using electron beam evaporation to function as a conductive seed layer.

The substrates were then electroplated at 20 mA/cm² with Ni using 0.36 M Ni(II) chloride solution as the electrolyte.

After the Ni electroplating, the substrate was dipped for 1 minute into a 15 mM solution mixture of Ni(II) and Fe(III) chloride at 1:1 molar ratio. The chloride ions in the solution initiated the corrosion process of the electroplated Ni film thereby forming NiFe double hydroxides at the film surface.

The substrates were finally dried at 70° C. for 1 hour.

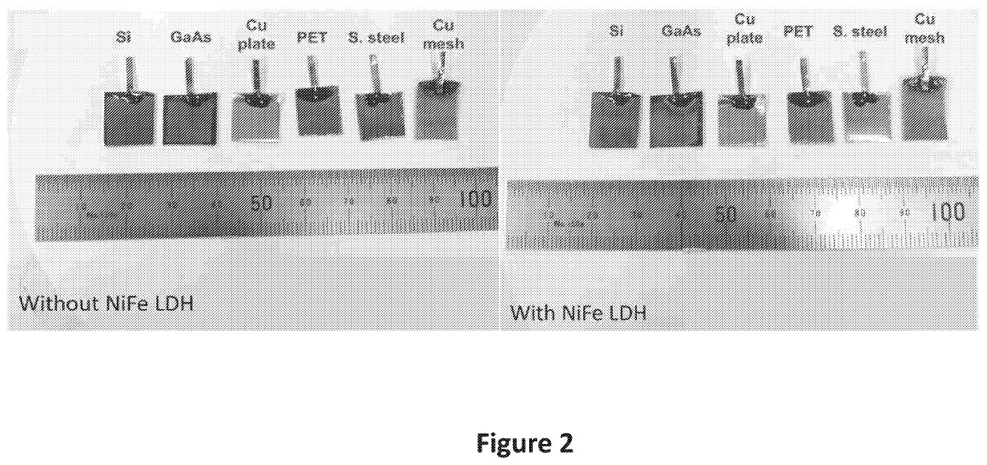

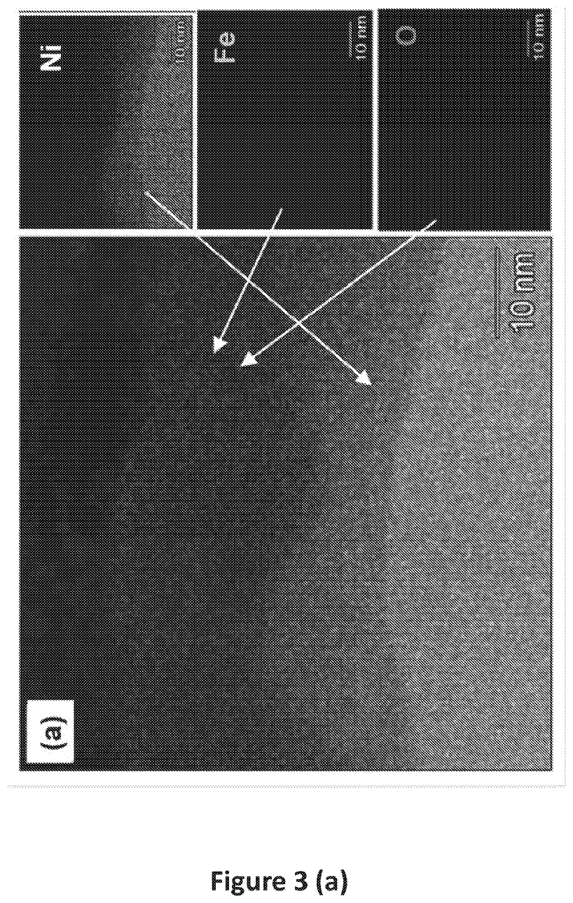

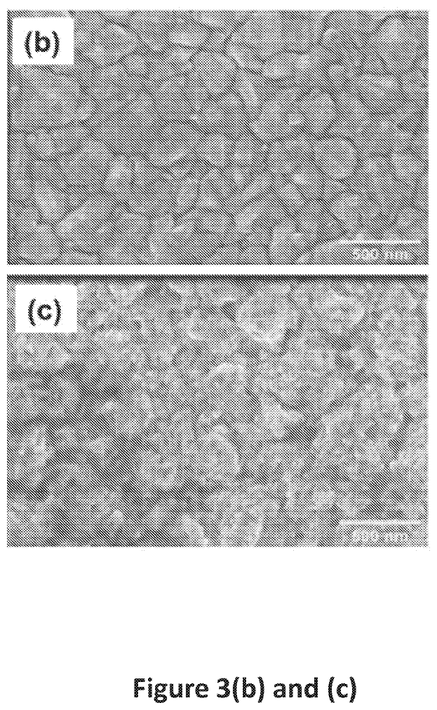

FIG. 2, shows photographs of Ni electroplated substrates before and after the formation of NiFe LDH. After the electroplating process, all the substrates showed uniform Ni film thickness across the substrate with good substrate-film adhesion. While the catalyst formation requires a degree of corrosion of the Ni film, the film integrity remains uncompromised by this process as shown in FIG. 3(a). FIG. 3(a) is an energy-dispersive spectroscopy (EDS) image of a cross-section region of a Ni electroplated substrate dipped in a solution mixture of Ni(II) and Fe(III) showing the NiFe LDH formed on a Ni surface. The EDS image shows a bottom layer (10-20 nm thick) comprised of Ni and a distinctive Fe/O layer (10-20 nm thick) on top of the Ni layer. The layer of Fe/O is indicative of the successful formation of the catalyst on the Ni surface through the corrosion process. As shown in FIG. 3(a) the layer of Fe/O does not permeate through the entire Ni metal layer, thereby safeguarding the integrity and the reusability thereof.

Once the chloride-solution dipping process is completed, it was possible to observe a visible change in the Ni film appearance in all substrates, whereby a brown rust-like appearance was noticed in contrast to the metallic grey appearance commonly seen in untreated Ni films.

The top-view scanning electron microscope (SEM) images in FIGS. 3(b) and (c) show a substantially corroded appearance on the previously pristine textured Ni film surface, indicating a thin catalyst layer formation on the surface.

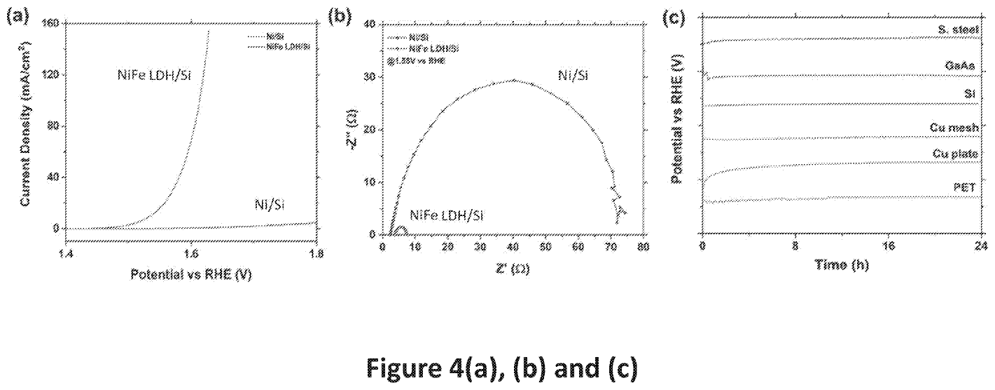

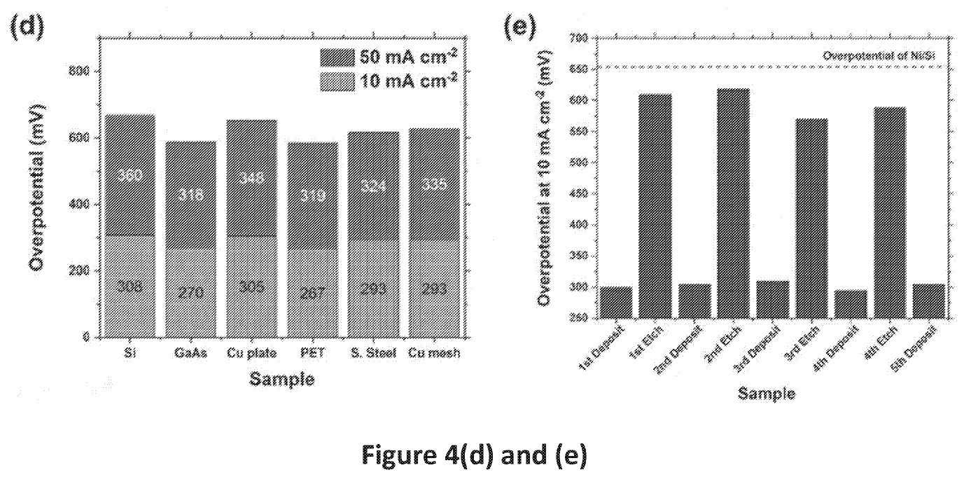

Voltammetric measurements of a Ni-electroplated Si substrate with and without the catalyst were performed to determine the catalytic improvement provided by the NiFe LDH. In particular, the OER performance of the Ni-electroplated Si substrate with and without the catalyst, respectively, were compared by connecting the substrate as a working electrode in a three-electrode cell with Pt plate and Ag/AgCl as counter and reference electrodes, respectively, at 1.0 M KOH solution (pH 13). The linear sweep voltammetry (LSV) curves of electroplated Ni on Si with and without NiFe LDH (FIG. 4(a)) shows demonstrably lower overpotential at 10 mA cm⁻² (308 mV) when the bimetallic hydroxide catalyst is present as compared to the pure Ni layer (630 mV).

Additionally, according to the Nyquist plot obtained from the electrochemical impedance spectroscopy (EIS) of the Ni-electroplated Si substrate with and without the catalyst (FIG. 4(b)), the catalyst supporting Si substrate shows greater OER reaction kinetics than the untreated Ni electroplated Si due to lower charge transfer resistance.

In terms of stability, the NiFe LDH catalyst was able to sustain OER activity at 10 mA cm⁻² for 24 hours without any major deviation in overpotential required (FIG. 4(c)), with similar behaviour observed for Ni plated S-steel and GaAs substrates.

The OER performance test was extended to all the assessed substrates of FIG. 2(a) and showed relatively consistent overpotential values at 10 and 50 mA cm⁻² (FIG. 4(d)), thereby demonstrating that the catalyst performance is substrate agnostic.

To demonstrate the reusability of the layer of metal applied to the substrate for multiple catalyst regeneration processes, the NiFe LDH catalyst was removed from the catalyst supporting Si substrate by treating the substrate with an etchant (hydrochloric acid (HCl) 0.1 M) for 10 minutes. The cleaned metal surface was then dipped in the 15 mM solution mixture of Ni(II) and Fe(III) chloride using the same dipping conditions of the first dipping process. The etching-corrosion process is repeated for four times. The overpotential was measured after each cycle to monitor changes in the catalyst performance.

FIG. 3(e) shows the overpotential measurements of the NiFe LDH catalyst on Si substrate before and after multiple cycles of etching the catalyst in 0.1 M of hydrochloric acid (HCl) for 10 minutes followed by regeneration of NiFe LDH using the same dipping conditions as the first dipping process. After each of the subsequent four etch-corrosion cycles, the catalyst performance remained relatively similar with no noticeable deterioration in performance. This demonstrates that the layer of Ni deposited on a substrate may be reused multiple times to form a layer of catalyst without the need of applying a fresh layer of metal on the substrate each time.

The method according to the present disclosure can also be used to stabilize catalysts for III-V semiconductor-based photoelectrode devices. III-V semiconductors exhibit good efficiency in (photovoltaic) PV and water splitting cells, but they can be sensitive to photo-corrosion in harsh electrolyte environments.

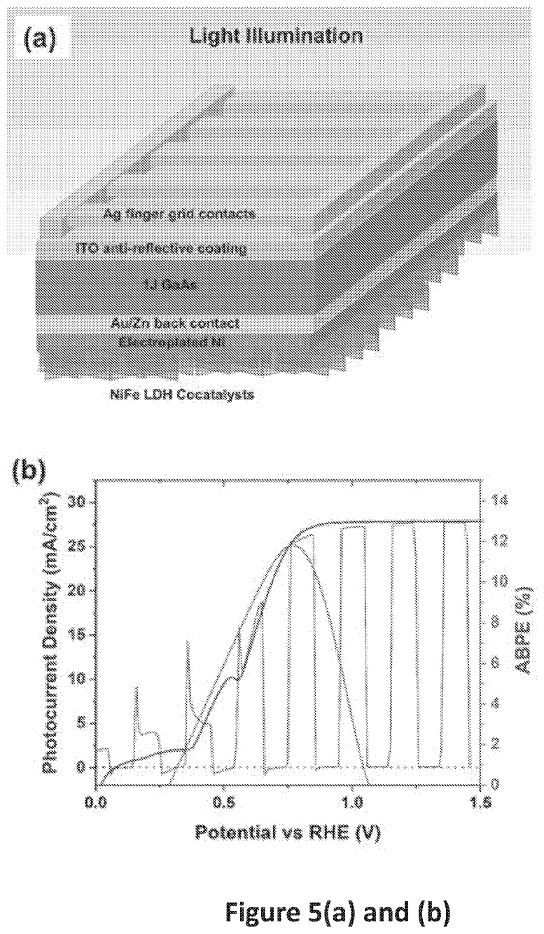

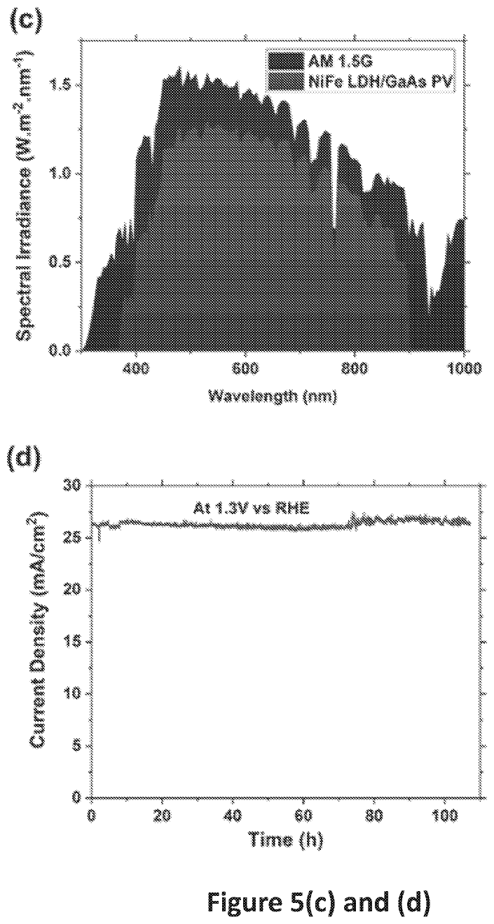

As schematically shown in FIG. 5(a), a commercial single-junction GaAs PV cell was electroplated with Ni at the rear contacts and dipped in the corrosive solution to form the catalyst layer as described above.

As shown in FIG. 5(b), at AM 1.5 G 1 sun illumination, the photoanode device achieved a saturated photocurrent density of approximately 27 mA/cm² (FIG. 5(b)), which is within the expected range for single junction GaAs PV cells. The device also exhibited a good photo-response throughout the measured potential range based on the generated photocurrent under illumination as compared to that in dark conditions. From the obtained JV curve, the ABPE was calculated to be approximately 11.7% at 0.52 V vs RHE (see FIG. 5(b)) which is an excellent ABPE value for the photoanode. Additionally, about 80% incident photon-to-current efficiency (IPCE) was achieved for this photoelectrode design in the spectral region of 500-800 nm (FIG. 5(c)). This demonstrates an overall good conversion efficiency of the photoelectrode, with some losses expected due to the absorbance and reflection by the encapsulating glass at the irradiation area of the PV cell. The stability of the photoanode device was assessed at the onset potential of saturated photocurrent density (1.3 V vs RHE), in which the device performance is sustained for 100 hours (FIG. 5(d)).

The experimental results discussed above and illustrated in the accompanying Figures demonstrate that the method according to the present disclosure can be used to construct and stabilise semiconductor electrodes for solar water splitting, achieving record levels of photoanode efficiency.

It is to be understood that, if any prior art publication is referred to herein, such reference does not constitute an admission that the publication forms a part of the common general knowledge in the art, in Australia or any other country.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1-75. (canceled)

76. A method of fabricating a catalyst on a substrate comprising:
providing the substrate;
applying a seed layer to the substrate;
forming a layer of metal on the seed layer, the layer of metal comprising one or more metals selected from Ni, Mo, Co, Fe, Cu, Mn and Zn; and
contacting the layer of metal with a corrosive metal halide solution to form the catalyst.

77. The method of claim 76, wherein the seed layer has a minimum thickness of approximately 50 nm.

78. The method of claim 76, wherein the seed layer has a thickness of approximately 100 nm.

79. The method of claim 76, wherein the seed layer comprises Ti and/or Ni.

80. The method of claim 79, wherein the seed layer comprises at least one of a layer of Ti and a layer of Ni.

81. The method of claim 76, wherein applying the seed layer to the substrate comprises depositing the seed layer by electron beam evaporation.

82. The method of claim 76, wherein applying the seed layer to the substrate comprises depositing the seed layer by thermal evaporation.

83. The method of claim 76, wherein applying the seed layer to the substrate comprises depositing the seed layer by sputter deposition.

84. The method of claim 76, wherein forming the layer of metal on the seed layer comprises electroplating the metal on the seed layer.

85. The method of claim 76, wherein the layer of metal has a thickness of 0.5 μm to 10 μm.

86. The method of claim 76, wherein the layer of metal is applied on the seed layer by electroplating the seed layer with a Ni(II) chloride solution as the electrolyte, to thereby form a layer of Ni on the seed layer.

87. The method claim 76, wherein the layer of metal comprises two or more metals.

88. The method of claim 76, wherein forming the layer of metal on the seed layer comprises applying a metal plate or foil on the seed layer.

89. The method of claim 76, wherein the substrate is an electrode.

90. The method of claim 76, wherein the substrate is a photovoltaic cell.

91. The method of claim 90, wherein substrate is a GaAs photovoltaic cell.

92. The method of claim 76, wherein the catalyst comprises one or more metal hydroxides.

93. The method of claim 76, wherein the corrosive metal halide solution is a transition metal halide solution.

94. The method of claim 93, wherein the corrosive metal halide solution comprises one or more transition metal chlorides.

95. The method of claim 94, wherein the corrosive metal halide solution comprises a mixture of Ni(II) and Fe(III) chlorides.
